(19) United States
(12) Patent Application Publication
(10) Pub. No.: US 2009/0313798 A1
(43) Pub. Date: Dec. 24, 2009

(54) RUGGED PIEZOELECTRIC ACTUATORS AND METHODS OF FABRICATING SAME

(75) Inventors: Alexander C. Edrington, Norfolk, VA (US); William F. Ott, Williamsburg, VA (US)

Correspondence Address: NIXON & VANDERHYE, PC, 901 NORTH GLEBE ROAD, 11TH FLOOR, ARLINGTON, VA, 22203, US

(73) Assignee: Adaptiv Energy ,LLC, Hampton, VA (US)

(21) Appl. No.: 12/521,909

(22) PCT Filed: Dec. 31, 2007
(86) PCT No.: PCT/US2007/026484

§ 371 Date: Jul. 1, 2009

Related U.S. Application Data
(60) Provisional application No. 60/882,693, filed on Dec. 29, 2006.

(51) Int. Cl. H01L 41/22

(52) U.S. Cl. 29/25.35

(57) ABSTRACT

Processes of fabricating an actuator comprises bonding an unpolled element to a substrate and thereafter poling the bonded element for providing the element with an electro-active response property. In differing modes of the process, the unpolled element can comprise one or more of (for example) a piezoelectric material (e.g., lead zirconate titanate); a piezorestrictive material; and/or a ferroelectric material. Actuators fabricated by the processes are also described.

This application claims the priority and benefit of U.S. Provisional Patent Application 60/882,693, filed Dec. 29, 2006, entitled, RUGGED PIEZOELECTRIC ACTUATORS AND METHODS OF FABRICATING SAME, which is incorporated herein by reference.

### BACKGROUND

I. Technical Field

This invention pertains to actuators and methods of fabrication thereof, particularly to actuators comprising an electro-active layer bonded or laminated to a metallic or substrate layer.

II. Related Art and Other Considerations

Some types of actuators have a construction in which a first component is bonded, laminated, or otherwise adhered to a second or substrate component. Typically the first component is electro-active, e.g., has a particular stimulus responsive property and can be, for example, piezoelectric, ferroelectric, ferroelastic, or pyroelectric. Historically the first component possesses its responsive property (e.g., piezoelectric) prior to the lamination or bonding process.

Referring briefly to the piezoelectric property as a representative one of the responsive properties, it is well known that a piezoelectric material is polarized and will produce an electric field when the material changes dimensions as a result of an imposed mechanical force. This phenomenon is known as the piezoelectric effect. Conversely, an applied electric field can cause a piezoelectric material to change dimensions.

According to some techniques, a laminated piezoelectric actuator is manufactured by bonding (e.g., by using adhesive or other means) one or more piezoelectric ceramic wafer(s) or element(s) to a substrate(s). One purpose of bonding the piezoelectric ceramic to the substrate is to maintain partial compressive load on the ceramic element such that when it is energized, it does not fracture under tension. A common substrate material is metal, often stainless steel, although other metals can also be used.

One type of laminated piezoelectric element is known as a ruggedized laminated piezoelectric or RLP®, which has a piezoelectric wafer which is laminated to a stainless steel substrate and preferably also has an aluminum cover laminated thereover. Examples of such RLP® elements, and in some instances pumps employing the same, are illustrated and described in one or more of the following: PCT Patent Application PCT/US01/28947, filed 14 Sep. 2001; U.S. patent application Ser. No. 10/380,547, filed Mar. 17, 2003, entitled “Piezoelectric Actuator and Pump Using Same”; U.S. patent application Ser. No. 10/380,589, filed Mar. 17, 2003, entitled “Piezoelectric Actuator and Pump Using Same”, and U.S. patent application Ser. No. 11/279,647 filed Apr. 13, 2006, entitled “PIEZOELECTRIC DIAPHRAGM ASSEMBLY WITH CONDUCTORS ON FLEXIBLE FILM”, all of which are incorporated herein by reference.

The bonding or lamination of a piezoelectric element such as a piezoelectric ceramic wafer to a substrate or other metallic layer can be performed using a hot melt adhesive. Bonding or lamination using a hot melt adhesive (including a polyimide adhesive such as that known as LaRC-SI™) is taught by one or more of the following United States patent documents (all of which are incorporated herein by reference): US Patent Publication US 2004/0117960 A1 to Kelley; U.S. Pat. No. 6,512,323 to Forck et al.; U.S. Pat. No. 5,849,125 to Clark; U.S. Pat. No. 6,030,480 to Face; U.S. Pat. No. 6,156,145 to Clark; U.S. Pat. No. 6,257,293 to Face; U.S. Pat. No. 5,632,841 to Hellbaum; U.S. Pat. No. 6,734,603 to Hellbaum. Other adhesive formulations or bonding/lamination techniques are taught by one or more of the following (all of which are incorporated herein by reference): U.S. Provisional Patent Application 60/877,630, entitled “HOT MELT THERMOSETTING POLYIMIDE ADHESIVES CONTAINING DIACETYLENE GROUPS”; U.S. Provisional Patent Application 60/882,677, entitled “POLYIMIDE/COPOLYIMIDE FILMS WITH LOW GLASS TRANSITION TEMPERATURE FOR USE AS HOT MELT ADHESIVES”; and PCT Patent Application PCT/US07/89006, filed Dec. 28, 2007, entitled “POLYIMIDE/COPOLYIMIDE FILMS WITH LOW GLASS TRANSITION TEMPERATURE FOR USE AS HOT MELT ADHESIVES”.

As mentioned above, a first component, such the wafer or layer which serves as a piezoelectric material, possesses its responsive property (e.g., piezoelectric property) prior to the lamination or bonding process. For example, the piezoelectric wafer is poled prior to the lamination.

### BRIEF SUMMARY

One aspect of the technology concerns processes of fabricating an actuator which comprise bonding an unpoled element to a substrate and thereafter poling the bonded element for providing the element with an electro-active response property. In differing modes of the process, the unpoled element can comprise one or more of (for example) a piezoelectric material (e.g., lead zirconate titanate); a piezorestrictive material; and/or a ferroelectric material.

An example embodiment includes the further act of using a polyimide adhesive for bonding the unpoled element to the substrate for forming a laminate. In an example implementation, the act of bonding the unpoled element to the substrate also bonds at least one conductive surface to the unpoled element for serving as element electrodes.

The poling act is thus a post-processing (e.g., post-laminating) processing treatment. The poling act can be preformed in accordance with any of several modes. For example, the poling act can occur using one or more of a selected electric field and/or a selected temperature condition, one or more of the selected electric field and/or a selected temperature condition being chosen in accordance with a desired dipole orientation and/or a desired polarization strength for the poled material. As another example, the poling act can occur using one or more of a selected electric field and/or a selected temperature condition, one or more of the selected electric field and/or a selected temperature condition being chosen in accordance with a desired stress state of a finished actuator.

As an optional further act, the process can further comprise, during the act of bonding the unpoled element to the substrate, also bonding at least one conductive surface to the unpoled element for serving as an electrode for the element.

Another aspect of the technology concerns actuators fabricated by the processes described herein and their variations.

### BRIEF DESCRIPTION OF THE DRAWINGS

The foregoing and other objects, features, and advantages of the invention will be apparent from the following more particular description of preferred embodiments as illustrated in the accompanying drawings in which reference characters refer to the same parts throughout the various views. The drawings are not necessarily to scale, emphasis instead being placed upon illustrating the principles of the invention.

FIG. 1 is a flowchart illustrating example steps or acts of a process of fabricating an actuator.

FIG. 2 is a diagrammatic view of example structure involved in the process of FIG. 1.

FIG. 3 is a diagrammatic view of another example structure involved in the process of FIG. 1.

FIG. 4 a diagrammatic view showing various example modes of post-processing for poling a bonded element.

FIG. 5 is a flowchart illustrating a variation of the process of FIG. 1.

### DETAILED DESCRIPTION

In the following description, for purposes of explanation and not limitation, specific details are set forth such as particular architectures, interfaces, techniques, etc. in order to provide a thorough understanding of the present invention. However, it will be apparent to those skilled in the art that the present invention may be practiced in other embodiments that depart from these specific details. That is, those skilled in the art will be able to devise various arrangements which, although not explicitly described or shown herein, embody the principles of the invention and are included within its spirit and scope. In some instances, detailed descriptions of well-known devices, circuits, and methods are omitted so as not to obscure the description of the present invention with unnecessary detail. All statements herein reciting principles, aspects, and embodiments of the invention, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

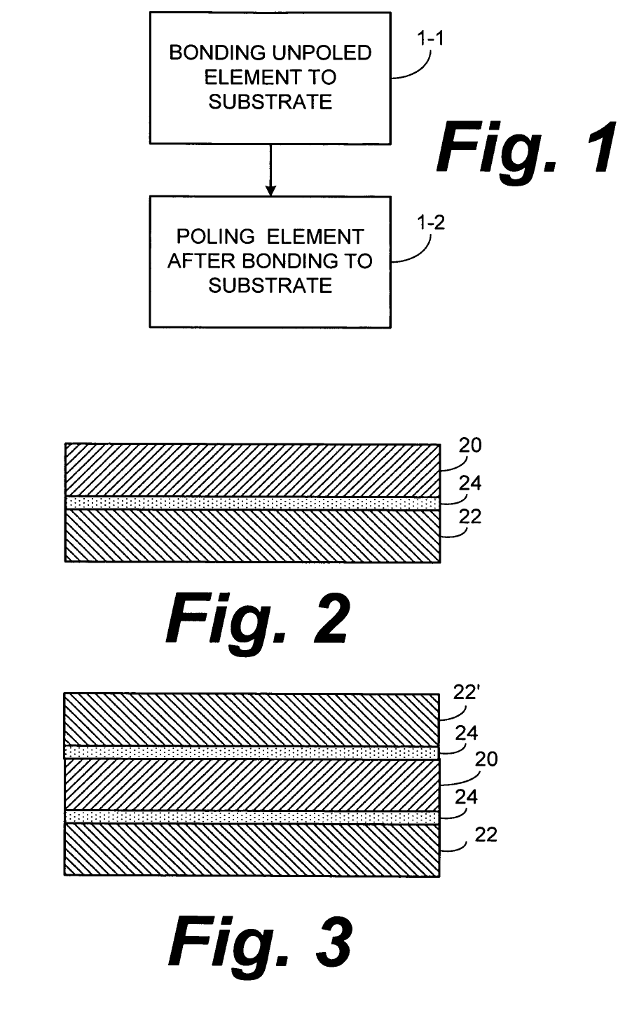

FIG. 1 shows a flowchart illustrating example, non-limiting steps or acts of a process of fabricating an actuator. FIG. 2 provides a diagrammatic view of structure involved in the process of FIG. 1. A first example act 1-1 of the process comprises bonding an unpoled element 20 (see FIG. 2) to another layer or substrate 22. A second example act 1-2 of the process comprises (after the bonding of act 1-1) poling the bonded element for providing the bonded element with an electro-active response property.

Preferably but not exclusively the act 1-1 of bonding comprises using a polyimide adhesive for bonding the unpoled element to the substrate for forming a laminate. Accordingly, FIG. 2 shows placement of a polyimide adhesive film 24 between the unpoled element 20 and the substrate 22. The use of a polyimide adhesive film 24 for bonding purposes is understood with reference to various above-referenced and already incorporated patent documents

Preferably but not exclusively the bonding act 1-1 of FIG. 1 also involves bonding the unpoled element 20 to a metallic layer, such as stainless steel or aluminum, for example. It should be understood that the bonding act 1-1 of FIG. 1 is not confined to the bonding of the unpoled element 20 to one layer. One or more layers can be bonded to unpoled element 20 during act 1-1. In this regard, FIG. 3 shows that two layers (e.g., substrate 22 and cover layer 22′) can be bonded to unpoled element 20 during an act such as act 1-1.

The process thus starts with an unpoled material, e.g., a material which initially has no electro-active response properties (e.g., is non-piezoelectric, non-ferroelectric, etc.). The bonding of act 1-1 thus occurs before any poling of the element 20. The poling act 1-2 is a post-processing (e.g., post-laminating) processing treatment which occurs after the bonding of the initially unpoled element 20 to the substrate.

When a poled piezoelectric component capable of producing high strain with applied electric field (such as PZT material, specifically Morgan Matroc 5A, Morgan Matroc 5H, CTS 3195, and CTS3203) is involved in a heating process which goes through the Curie temperature of the material or comes reasonably close to the Curie temperature (say, within 100° C.), the resulting strain in the material is extraordinary and results in a more frequent ceramic fracture since the part is not in compression at this elevated processing temperature. Therefore, unlike conventional processes, during thermal processing (such as bonding) there need be no concern regarding Curie temperature or temperature of depoling for the unpoled element 20. Moreover, an unpoled (e.g., non-piezoelectric) component does not suffer from the afore-described and other problems so that processing yields and stress-bias controllability are much improved.

In differing modes of the method, the unpoled element 20 can comprise one or more of (for example) a piezoelectric material (e.g., lead zirconate titanate); a piezorestrictive material; and/or a ferroelectric material. For example, for one embodiment/mode the unpoled element 20 can be lead zirconate titanate existing without piezoelectric property (but which, after the poling of act 1-2, acquires a piezoelectric response property).

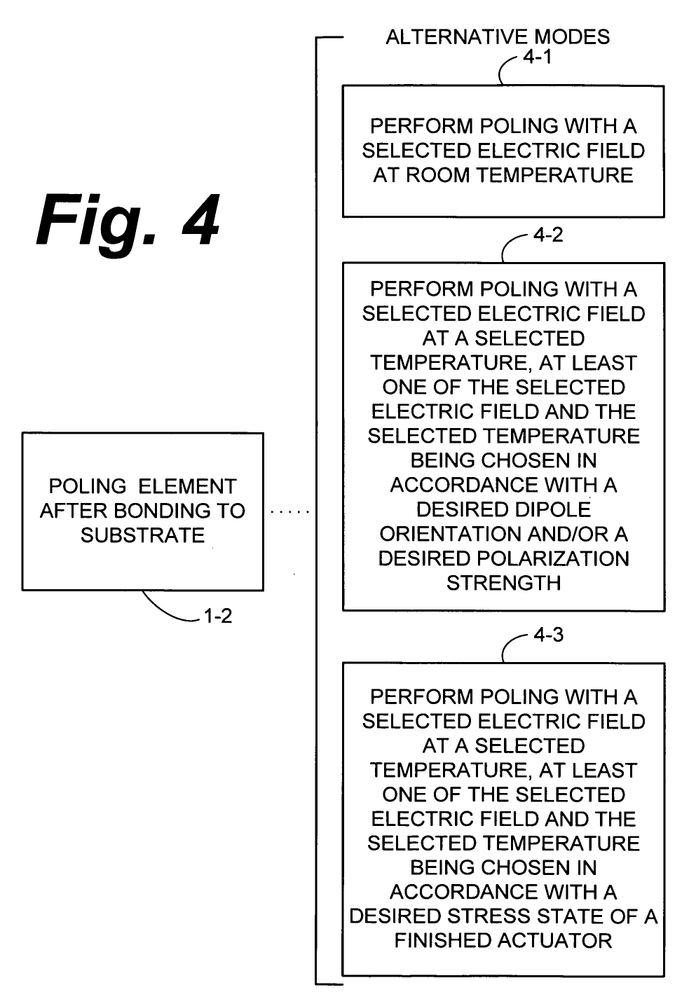

Poling act 1-2 can be preformed in accordance with any of several different modes in which poling condition parameters are controlled in respective different ways. The poling condition parameters for act 1-2 include applied voltage level and temperature (e.g., temperature range). Three non-limiting example modes for performing the poling 1-2 are illustrated in FIG. 4.

According to a first example mode 4-1, the poling of the element is performed with a selected electric field at room temperature (e.g., after device cooling, e.g., after cooling of the laminate). According to a second example mode 4-2, the poling of the element is performed with a selected electric field at a selected temperature, at least one of the selected electric field and the selected temperature being chosen in accordance with a desired dipole orientation and/or a desired polarization strength. According to a third example mode 4-3, the poling of the element is performed with a selected electric field at a selected temperature, at least one of the selected electric field and the selected temperature being chosen in accordance with a desired stress state of a finished actuator.

The temperature for performing poling act 1-2 can be set or selected in accordance with several different temperature control scenarios. For example, the poling of act 1-2 can be performed at a given (e.g., selected) cooling temperature; through a given (e.g., selected) cooling temperature range; at a given (e.g., selected) heating temperature; through a given (e.g., selected) heating temperature range; or through a given (e.g., selected) heating and cooling temperature range. Thus, in some implementations the poling may occur over a “range” (e.g., selected range) of temperatures rather than at a specific constant temperature. As mentioned above with respect to FIG. 4, the selection of the temperature (e.g., temperature range) can be in accordance with a desired dipole orientation and/or a desired polarization strength, or in accordance with a desired stress state of a finished actuator.

The applied voltage level parameter for the poling of act 1-2 can be selected in various ways. For example, the applied voltage level parameter can be selected as constant, or changing (e.g., ramped) over a period of time. In one example implementation, poling occurs at a known constant applied voltage level (such as +600V for 3 seconds). In another example implementation, poling act 1-2 begins with an applied voltage of +0V for 0.1 second, followed by a one second linear ramp from +0V to +600V, followed by a hold at +600V for 3 seconds, followed by a 1 second linear ramp down from +600V to +0V). As mentioned above with respect to FIG. 4, the selection of the applied voltage parameter can be in accordance with a desired dipole orientation and/or a desired polarization strength, or in accordance with a desired stress state of a finished actuator. Thus, in another example implementation, the poling of act 1-2 occurs at room temperature and by ramping the applied voltage from +0V to +650V in one second, holding applied voltage at +650V for three seconds, and then ramping down from +650V to +0V in one second. In some embodiments, poling voltage magnitude and time depends on the thickness of the wafer and the wafer's formulation as well as the desired final properties (i.e., stress state) of the actuator.

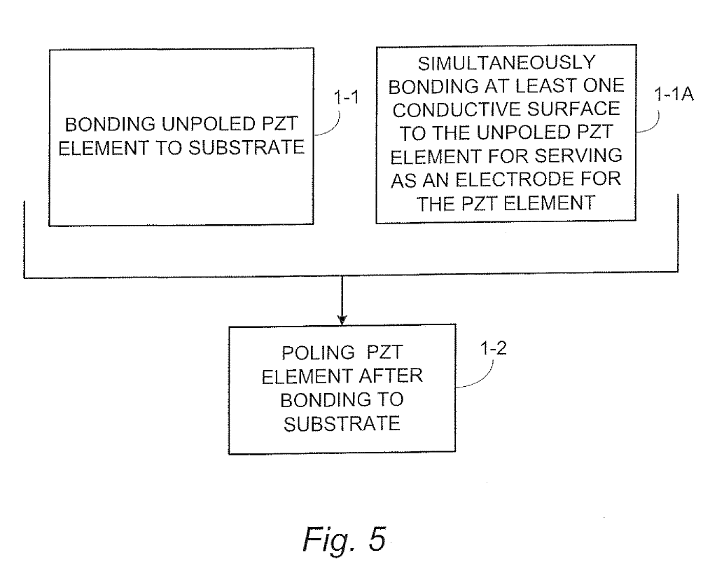

The process of FIG. 1 presumed that the unpoled element 20 already had electrodes formed on surfaces thereof (e.g., opposing major surfaces of a wafer, for example). The electrodes of the unpoled element 20 of FIG. 1 are not illustrated. FIG. 5 illustrates a variation of the process of FIG. 1 wherein, as an optional further act 1-1A, the process further comprises, during the act 1-1 of bonding the unpoled element to the substrate, also bonding at least one conductive surface to the unpoled element for serving as an electrode for the element.

Thus, as represented in example fashion by FIG. 5, a secondary embodiment involves purchasing unelectroded and hence unpoled material (e.g., unpoled element 20), applying major conductive surfaces to the major ceramic surfaces during the thermal bonding process in which the unpoled material is bonded to the substrate, and subsequently poling to create an actuator in which the material bonded to the substrate is imparted with an electro-active response property.

An example structure which can result from the process of FIG. 1 is a ruggedized laminated piezoelectric construct, with main components including a stainless disc, polyimide film, lead zirconate titanate (PZT) component with two major surfaces containing a metallic electrode, polyimide film, and an optional second pre-stress layer. The process basically involves selecting an unpoled (and hence non-ferroelectric, non-piezoelectric, non-ferroelastic, etc.) PZT component prestressed via bonding all major internal metallic surfaces with the polyimide film layers, and choosing any appropriate post-processing poling treatments (such as the examples described in FIG. 5) to provide the device with its desired piezoelectric response.

Case Study 1

In trial demonstration (case study 1), ruggedized laminated piezoelectric actuators were built from unpoled ceramics. A control group of poled ceramics was also built for case study 1 for performance comparison purposes. All actuators were processed identically (pressure, temperature, constituent materials). Two different post-bonding poling treatments were attempted: 2 kV/mm at 50 C and 3 kV/mm at 70 C. For the 200 um thick PZT elements used in the demonstration, the resulting voltages applied were +400 VDC and +600 VDC, respectively.

The above experiment was initially performed with Kyocera KPM-31 type PZTs. It was replicated on the same day with C3900 PZTs supplied by Alpha ceramics.

After poling at 2 kV/mm and 50 C, devices built from non-ferroelectric KPM-31 ceramics average a higher actuator center displacement upon 60 Hz 400 Vpp excitation than the control group (79.0 micron vs. 75.1 micron) while drawing significantly less current (2.23 ma vs. 2.45 ma rms). The decrease in current draw was more pronounced during 60 Hz 500 Vpp excitation (2.78 ma vs. 3.10 ma rms), while the gains in displacement remained comparable (99.2 micron vs. 93.9 micron).

Devices built with the C3900 PZTs exhibited a much improved displacement when subjected to the 3 kV/mm at 70 C poling treatment (137.5 micron with 400 Vpp at 60 Hz) compared to the 2 kV/mm at 50 C poling (117.0 micron). All devices for C3900 had to be poled post-processing due to the process temperature (280 C) being substantially higher than the material's Curie temperature (190 C).

Case Study 2

Case Study 2 demonstrates, e.g., an example of stress state control via post poling. In case study 2, for comparison purposes a first set of twenty already-poled piezoelectric wafers (CTS 3195) were utilized. The as-poled (e.g., already poled) piezoelectric wafers of the first set were 25 mm in diameter, 0.200 mm thick, and exhibited a post-laminating average dome height of 164.4 micrometers. Due to the effects of the laminating process (applied temperature and pressure) on the polarization strength of these previously poled wafers, the as-laminated wafers had to be re-poled with a field strength of +600V for a duration of 6 seconds at 25° C. Upon this post-poling operation, the average dome height of these twenty actuators was 83.5 micron. These actuators comprised a first pre-stress layer of stainless steel (alloy 301) with a thickness of 100 micrometers, a first polyimide adhesive layer with a thickness of 25 micrometers, the aforementioned piezoelectric element, a second polyimide adhesive layer with a thickness of 25 micrometers, and a second pre-stress layer of BeCu-25 with a thickness of 12.5 micrometers.

On the same day, and as a second aspect of case study 2, a second set of twenty unpoled elements (e.g., elements constructed as un-poled and therefore non-piezoelectric, non-ferroelectric) were fabricated and tested. The unpoled elements of the second set were also piezoelectric wafers (CTS 3195) taken from the same material slug as the comparative examples of the same case study. The unpoled elements of the second set were also 25 mm in diameter, 0.200 mm thick, but exhibited a post-laminating average dome height of 238.7 micrometers. These second set devices were given a first poling as-laminated with a field strength of +600V for a duration of six seconds at 25° C. Upon this poling operation, the average dome height of these twenty actuators of the second set was 0.4 micron. These actuators comprised a first pre-stress layer of stainless steel (alloy 301) with a thickness of 100 micrometers, a first polyimide adhesive layer with a thickness of 25 micrometers, the aforementioned non-piezoelectric PZT element, a second polyimide adhesive layer with a thickness of 25 micrometers, and a second pre-stress layer of BeCu-25 with a thickness of 12.5 micrometers.

For disc-shaped wafer constructs such as those of the foregoing case study, the dome height is a measure of pre-stress and determines the maximum compressive and tensile loads experienced by the ceramic element. Dome height is measured by positioning the first pre-stress layer (SS301) of the disc in contact with a flat base plate containing a hole concentric with the center of the pre-stress layer disc. A non-contact transducer is then used to measure the static positional difference of the center of the disc from the disc's perimeter, the latter of which is in contact with the flat base plate; this difference is reported as the dome height.

In many cases, a higher pre-stress (with corresponding greater dome height) is not desired when incorporating pre-stressed actuators into practical uses. One of these cases exists wherein the pre-stress results in a significantly non-dome shaped actuator, e.g., the higher pre-stress results in an “arcuate” or “potato-chipped” shape that does not have the symmetry of a dome. For example, actuators from FACE International, specifically model TH-5C, display a significant non-dome shape due to a large amount of pre-stress present. The TH-5C actuator is not practicable in many uses because of difficulty in constraining the actuator along its edge or perimeter. For example, an “arcuate” or “potato-chipped” actuator can not be easily sealed using gaskets or O-rings for functioning within a liquid pump, nor can it be captured in a well-known “simply supported” condition along the perimeter for applications such as active valving and precision motion control. In these cases, an actuator with a true dome shape such as the RLP® ruggedized laminated actuator produced using the methods described herein presents a significant technical advantage, as its edge (i.e., perimeter) can be captured properly using standard practices without detrimental effects to the actuator.

The root of the “arcuate” or “potato-chipped” shaping of an actuator is significantly contributed to by any anisotropic properties present in the actuator's constituent components. For example, a stainless disc produced from commonly incorporated and cost-effective methods (e.g., cold rolling, hot rolling, cold rolling followed by annealing, etc.) possesses distinct anisotropy that will impart a non-uniform stress to a disc-shaped actuator when used for thermal pre-stress purposes as a pre-stress layer. This anisotropy combined with geometric nonlinearities within the constituent materials is amplified with an increasing amount of pre-stress such as is present in TH-5C actuator, resulting in a non-dome shaped actuator.

Control of the pre-stress such that the PZT is in partial compression but does not exceed a dynamic tensile stress limit of the PZT and such that the dome height can be controlled to a lower level result in actuators with a technical advantage as they present a proper dome-shape geometry (for disc-shaped actuators). The methods/processes described hereincan be extended to non-disc shaped actuators, for example rectangular actuators or polygon-shaped actuators, as the same benefits transfer independent of the desired/selected actuator shape.

In some instances a higher dome height such as what resulted in the first set of case study 2 may be beneficial. Using the RLP® construct as an example, the actuators from the first batch experience a higher tensile stress at the major surface of the electro-active element opposite the first pre-stress layer while also experiencing a higher compressive stress in the electro-active element at the major surface nearest the first pre-stress layer. A zero stress level exists within the electro-active element on a plane between its first and second major surfaces.

In the second set of case study 2, the electro-active element also experiences its maximum tensile stress at the major surface opposite the first pre-stress layer and its maximum compressive stress at the major surface nearest the first pre-stress layer. However, the difference between the maximum tensile and maximum compressive stresses is significantly lower than that experienced in the first set of case study 1 due to the significantly lower amount of pre-stress induced by thermal mismatch (as reflected in the resulting dome height). In the second case study, the electro-active (e.g., PZT) element within the actuators built in the second set experience a significantly lower peak tensile stress than the electro-active (e.g., PZT) element within actuators built in the first set of the second case study.

An advantage of the processes described herein and the actuators fabricated thereby is that the final stress condition in the electro-active element (e.g., PZT) can be selected by controlling when the first poling of the element takes place. For example, the first set of case study 2 would be a condition wherein the poling cycle was controlled at a point prior to actuator bonding and prior to the actuator process reaching a temperature near the Curie temperature of the electro-active element (the Curie temperature only existing when the electro-active element has received a poling treatment). The second set of case study 2 would be a condition wherein the poling cycle was controlled at a point after actuator bonding and after the actuator had cooled to room temperature (20-27° C.).

In the aforementioned RLP® cases, the PZT is controlled to a partial compressive stress (not a complete compressive stress state), and therefore the contributions of geometric nonlinearities and component anisotropies are significantly lower compared to other documented methods for making a pre-stressed actuator.

The foregoing including the case studies provide examples of processing modes and products resulting therefrom. Variations of the poling parameters allow for further control of final actuator stress state. For example, such variations include poling at a given cooling temperature or through a range of cooling temperatures, poling at a given heating temperature or through a range of heating temperatures, poling through a given heating and cooling temperature range or ranges.

Advantages of the technology herein described include the ability to purchase unpoled, and therefore potentially un-electroded ceramics to use for building into piezoelectric actuators. Eliminating poling and eventually electrode surfaces reduces total cost of the actuators. Gaining control of poling cycle post-lamination allows for controlling stress state and poling strength unavailable when starting with a poled ceramic.

Although the description above contains many specificities, these should not be construed as limiting the scope of the invention but as merely providing illustrations of some of the presently preferred embodiments of this invention. Thus the scope of this invention should be determined by the appended claims and their legal equivalents. Therefore, it will be appreciated that the scope of the present invention fully encompasses other embodiments which may become obvious to those skilled in the art, and that the scope of the present invention is accordingly to be limited by nothing other than the appended claims, in which reference to an element in the singular is not intended to mean “one and only one” unless explicitly so stated, but rather “one or more.” All structural, chemical, and functional equivalents to the elements of the above-described preferred embodiment that are known to those of ordinary skill in the art are expressly incorporated herein by reference and are intended to be encompassed by the present claims. Moreover, it is not necessary for a device, process, or method to address each and every problem sought to be solved by the present invention, for it to be encompassed by the present claims. Furthermore, no element, component, or method step in the present disclosure is intended to be dedicated to the public regardless of whether the element, component, or method step is explicitly recited in the claims. No claim element herein is to be construed under the provisions of 35 U.S.C. 112, sixth paragraph, unless the element is expressly recited using the phrase “means for.

What is claimed is:

1. A process of fabricating an actuator comprising:
bonding an unpoled element to a substrate; and thereafter
poling the bonded element for providing the element with an electro-active response property.

2. The process of claim 1, wherein the unpoled element comprises lead zirconate titanate.

3. The process of claim 1, wherein the unpoled element comprises a piezoelectric material.

4. The process of claim 1, wherein the unpoled element comprises a piezorestrictive material.

5. The process of claim 1, wherein the unpoled element comprises a ferroelectric material.

6. The process of claim 1, further comprising using a polyimide adhesive for bonding the unpoled element to the substrate for forming a laminate.

7. The process of claim 1, further comprising poling the element with a selected electric field at room temperature.

8. The process of claim 1, further comprising poling the element with a selected electric field chosen in accordance with a desired dipole orientation and/or a desired polarization strength.

9. The process of claim 1, further comprising poling the element at a selected temperature chosen in accordance with a desired dipole orientation and/or a desired polarization strength.

10. The process of claim 1, further comprising poling the element with a selected electric field chosen in accordance with a desired stress state of a finished actuator.

11. The process of claim 1, further comprising poling the element at a selected temperature chosen in accordance with a desired stress state of a finished actuator.

12. The process of claim 1, further comprising, during the act of bonding the unpoled element to the substrate, also bonding at least one conductive surface to the unpoled element for serving as element electrodes.

13. A process of fabricating an actuator comprising:
bonding an element to a substrate; and
controlling a stress condition in the element by controlling timing of poling the element for providing the element with an electro-active response property.

14. An actuator fabricated by the process of claim 1.

15. An actuator fabricated by the process of claim 2.

16. An actuator fabricated by the process of claim 3.

17. An actuator fabricated by the process of claim 4.

18. An actuator fabricated by the process of claim 5.

19. An actuator fabricated by the process of claim 6.

20. An actuator fabricated by the process of claim 7.

21. An actuator fabricated by the process of claim 8.

22. An actuator fabricated by the process of claim 9.

23. An actuator fabricated by the process of claim 10.

24. An actuator fabricated by the process of claim 11.

25. An actuator fabricated by the process of claim 12.

26. An actuator fabricated by the process of claim 13.
